(19) United States
(12) Patent Application Publication
(10) Pub. No.: US 2026/0147062 A1
(43) Pub. Date: May 28, 2026

(54) SYSTEM AND METHOD FOR DETERMINING CABLE OPERATIONAL QUALITY BASED ON ENVIRONMENT WHERE CABLE IS LOCATED

(71) Applicant: GUANGZHOU PANYU CABLE GROUP CO., LTD., Guangzhou (CN)

(72) Inventors: Chaoqiang HU, Guangzhou (CN); Yingmin HUANG, Guangzhou (CN); Qianneng WANG, Guangzhou (CN); Weiguang GAO, Guangzhou (CN); Kemin ZOU, Guangzhou (CN); Yuanpeng SHAO, Guangzhou (CN); Cuishan XU, Guangzhou (CN); Zhihao LIANG, Guangzhou (CN); Fangqun YOU, Guangzhou (CN); Zhanpeng YANG, Guangzhou (CN); Ming DING, Guangzhou (CN); Shiliang WU, Guangzhou (CN); Chunhui DENG, Guangzhou (CN); Junyu ZHANG, Guangzhou (CN); Jingchang ZHOU, Guangzhou (CN); Xiaoliang HUANG, Guangzhou (CN); Hongfei XUE, Guangzhou (CN); Guozhen LI, Guangzhou (CN); Dewen YIN, Guangzhou (CN)

(21) Appl. No.: 19/400,615

(22) Filed: Nov. 25, 2025

(30) Foreign Application Priority Data
Nov. 26, 2024 (CN) 202411706493.0

(51) Int. Cl. G01R 31/58; G01R 31/00; G01R 31/12

(52) U.S. Cl. CPC G01R 31/58; G01R 31/1272; G01R 31/003

(57) ABSTRACT

The present application discloses a system and a method for determining cable operational quality based on an environment where a cable is located. The method includes: acquiring collected data of individual cable environment parameters within a preset time period and a plurality of associated cable operational quality influencing factors of individual cables, and determining cable environment parameter influencing values of the individual cable operational quality influencing factors correspondingly based on the collected data of the individual cable environmental parameters; in the presence of a plurality of cable environment parameter influencing values for each of the cable operational quality influencing factors, determining a final analysis value for the cable operational quality influencing factor based on the individual cable environment parameter influencing values of the cable operational quality influencing factor and pre-stored attributes of each associated individual cable environment parameter.

### CROSS-REFERENCE TO RELATED APPLICATION

This application claims priority to Chinese Patent Application No. CN202411706493.0 filed on Nov. 26, 2024, the entire content of which is hereby incorporated by reference.

### FIELD OF TECHNOLOGY

Embodiments of the present application relate to the technical field of cable monitoring, and in particular to a system and a method for determining cable operational quality based on an environment where a cable is located.

### BACKGROUND

Cables are an indispensable and important part of modern industry and life, and their safe and reliable operation is crucial for the production and life across all sectors. However, during use, the cables are susceptible to environmental factors such as temperature, humidity and oxygen concentration, which directly affect the operational quality of the cables. For example, excessively high ambient humidity causes the insulation layers of the cables to absorb moisture, leading to a decrease in insulation performance and an increase in electric leakage risk and resistance value, which thus trigger short circuits. In addition, excessively low oxygen concentration around the cables may cause the cable to overheat, increasing the risk of cable fires.

In the related art, the values of cable operational parameters are first detected in most cases, and the cable operational quality is then evaluated based on the values of the individual operational parameters. In this way, there is a lack of references regarding cable operational quality influencing factors, resulting in poor rationality of cable operational quality.

### SUMMARY

Embodiments of the present application disclose a system and a method for determining cable operational quality based on an environment where a cable is located.

According to a first aspect, the present application provides a method for determining cable operational quality based on an environment where a cable is located, which includes:
acquiring collected data of individual cable environment parameters within a preset time period and a plurality of associated cable operational quality influencing factors of individual cables, and determining cable environment parameter influencing values of the individual cable operational quality influencing factors correspondingly based on the collected data of the individual cable environmental parameters;
in the presence of a plurality of cable environment parameter influencing values for each of the cable operational quality influencing factors, determining a final analysis value for the cable operational quality influencing factor based on the individual cable environment parameter influencing values of the cable operational quality influencing factor and pre-stored attributes of each associated individual cable environment parameter;
in the presence of one cable environment parameter influencing value for each of the cable operational quality influencing factors, determining the cable environment parameter influencing value as a final analysis value for the cable operational quality influencing factor; and
determining a cable operational quality evaluation value based on the individual final analysis values and preset evaluation rules, including: retrieving a corresponding pre-stored operational quality evaluation value mapping table respectively based on the individual final analysis values to obtain corresponding evaluation values to be calculated, and comparing the evaluation values to be calculated with a preset standard value; and determining whether an evaluation value to be calculated that is lower than the preset standard value is present, and determining the cable operational quality evaluation value based on a determination result and the individual evaluation values to be calculated.

According to a second aspect, the present application provides an device for determining cable operational quality based on an environment where a cable is located, which includes:
one or more processors; and a storage means for storing one or more programs, the one or more programs, when executed by the one or more processors, cause the one or more processors to implement the method for determining cable operational quality based on the environment where the cable is located according to the first aspect.

According to a third aspect, the present application provides a storage medium for storing a computer-executable instruction, the computer-executable instruction, when executed by a computer processor, is configured to execute the method for determining cable operational quality based on the environment where the cable is located according to the first aspect.

### BRIEF DESCRIPTION

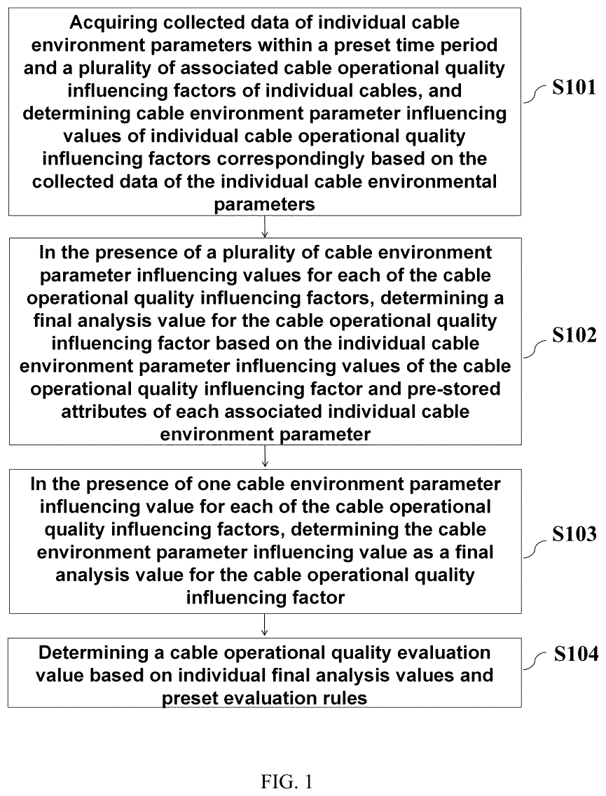

FIG. 1 shows a flowchart of a method for determining cable operational quality based on an environment where a cable is located according to an embodiment of the present application;

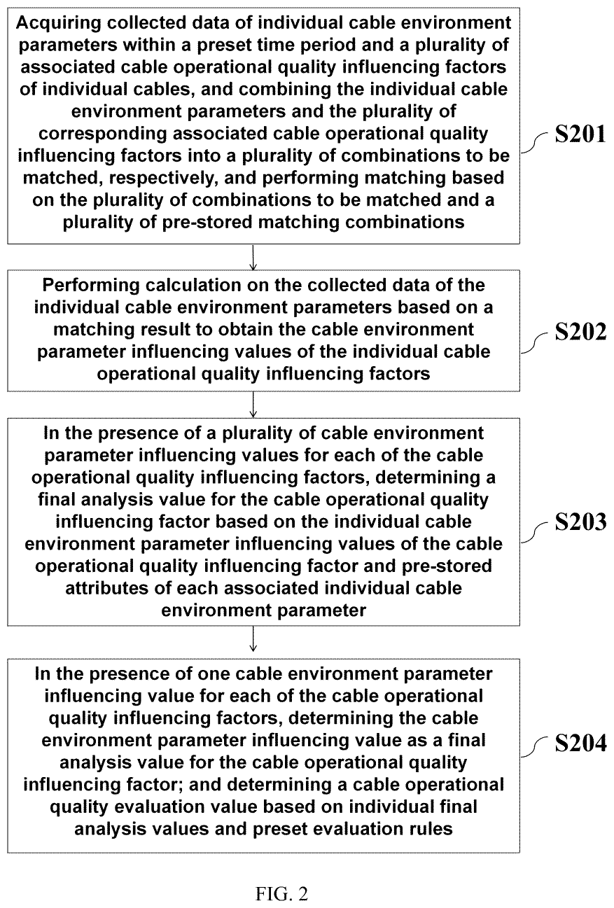

FIG. 2 shows a flowchart of another method for determining cable operational quality based on an environment where a cable is located according to an embodiment of the present application;

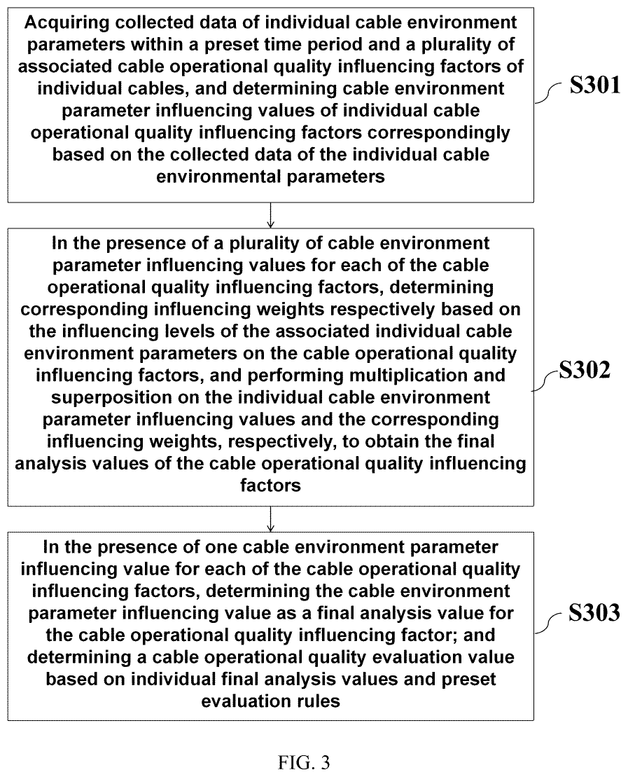

FIG. 3 shows a flowchart of another method for determining cable operational quality based on an environment where a cable is located according to an embodiment of the presentapplication;

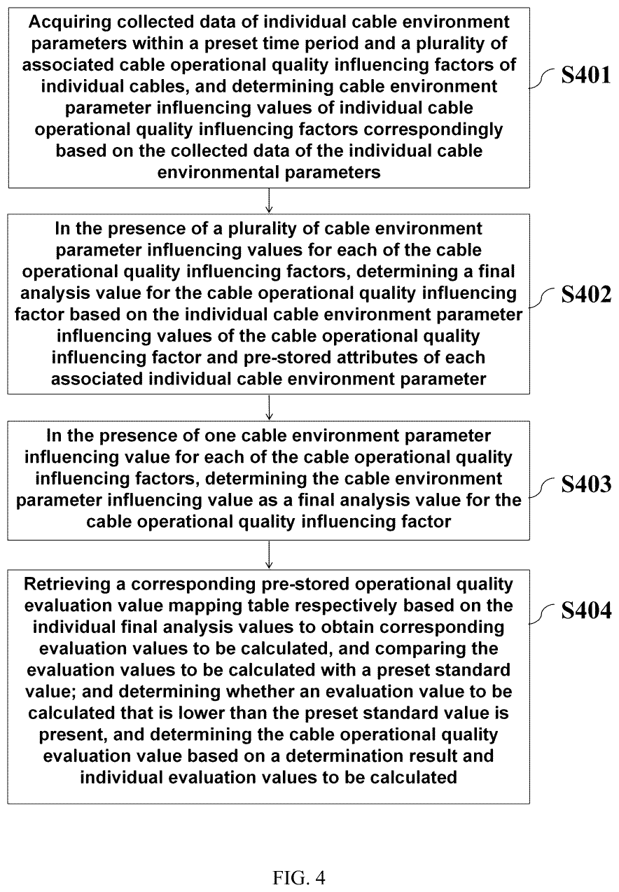

FIG. 4 shows a flowchart of another method for determining cable operational quality based on an environment where a cable is located according to an embodiment of the present application;

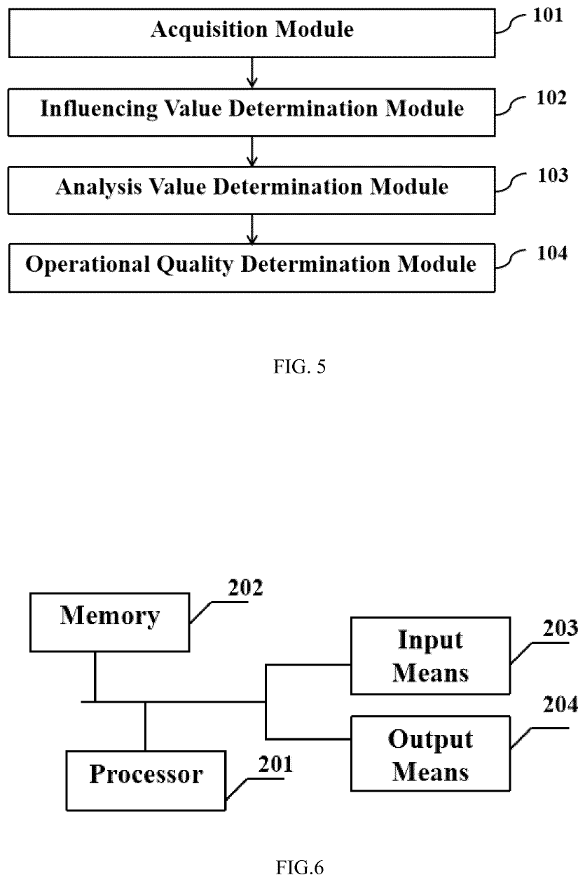

FIG. 5 shows a block diagram of a modular structure of a system for determining cable operational quality based on an environment where a cable is located according to an embodiment of the present application; and

FIG. 6 shows a schematic structural diagram of a device for determining cable operational quality based on an environment where a cable is located according to an embodiment of the present application.

### DETAILED DESCRIPTION

The embodiments of the present application will be further illustrated below in conjunction with the accompanying drawings and the embodiments. It can be understood that the specific embodiments described here are merely for the purpose of explaining the embodiments of the presentapplication, and are not intended to limit the embodiments of the present application. In addition, it should be noted that for the convenience of description, the accompanying drawings only show a part instead of all of the structure related to the embodiments of the present application.

In the specification and claims of the present application, the terms “first”, “second” and the like are intended for distinguishing similar objects, instead of describing a specific order or sequence. It should be understood that the data used in this way are interchangeable where appropriate, such that the embodiments of the present application can be implemented in an order other than those illustrated or described here. Moreover, objects distinguished by “first”, “second” and the like generally belong to the same class, rather than limiting the number of objects. For example, a first object may refer to one or more objects. Furthermore, “and/or” in the specification and claims indicates the inclusion of at least one of the objects connected thereby, while the character “/” generally indicates an “or” relationship between the front and back objects associated thereby.

The method for determining cable operational quality based on the environment where the cable is located provided by the embodiments of the present application can be applied to the scene of determining cable operational quality. In the method for determining cable operational quality based on the environment where the cable is located provided by the embodiments of the present application, an executive subject of each step may be a computer device that refers to any electronic device with capabilities of data calculation, processing and storage, such as a mobile phone, a PC (personal computer), a tablet computer and other terminal devices, or may be a server or other devices, which are not limited in the embodiments of the present application.

FIG. 1 shows a flowchart of a method for determining cable operational quality based on an environment where a cable is located according to an embodiment of the present application. As shown in FIG. 1, the method specifically includes the steps as follows.

In step S101, collected data of individual cable environment parameters within a preset time period and a plurality of associated cable operational quality influencing factors of individual cablesare acquired, and cable environment parameter influencing values of the individual cable operational quality influencing factors are determined correspondingly based on the collected data of the individual cable environmental parameters.

Here, the preset time period may be a period of time that is preset according to actual conditions. The cable environment parameters are used to represent the individual parameters (e.g., temperature, humidity, oxygen concentration and other cable environment parameters) of an ambient environment of the cable. The collected data may be the individual parameter values of the cable environment parameters that are collected within the preset time period. The cable operational quality influencing factors are used to represent factors affecting the cable operational quality, for example, fire, short circuit and other cable operational quality influencing factors. The cable environment parameter influencing values are used to represent the influencing values of the cable environment parameters on the associated cable operational quality influencing factors. In an embodiment, after the collected data of the individual cable environment parameters within the preset time period and the plurality of associated cable operational quality influencing factorsof individual cablesare acquired, a set of influencing value calculation formulas associated with the individual cable environment parameters is acquired; the plurality of cable operational quality influencing factors associated with the cable environment parameters are matched with the individual influencing value calculation formulas in the set of influencing value calculation formulas to obtain corresponding influencing value calculation formulas; and the collected data of the cable environment parameters are substituted into the individual influencing value calculation formulas to correspondingly obtain the cable environment parameter influencing values of the associated individual cable operation quality influencing factors. Optionally, a method for determining cable environment parameter influencing values of cable operational quality influencing factors may include: ombining the individual cable environment parameters and the plurality of corresponding associated cable operational quality influencing factors into a plurality of combinations to be matched, respectively; performing matching based on the plurality of combinations to be matched and a plurality of pre-stored matching combinations; and performing calculation on the collected data of the individual cable environment parameters based on a matching result, respectively, to obtain the cable environment parameter influencing values of the individual cable operational quality influencing factors. The cable environment parameters and the plurality of corresponding associated cable operational quality influencing factors are combined, matching is then performed based on the individual combinations, and the calculation is performed on the collected data of the cable environment parameters based on the matching result. In this way, the cable environment parameter influencing values of the individual cable operational quality influencing factors can be calculated rapidly and accurately.

In step S102, in the presence of a plurality of cable environment parameter influencing values for each of the cable operational quality influencing factors, a final analysis value for the cable operational quality influencing factor is determined based on the individual cable environment parameter influencing values of the cable operational quality influencing factor and pre-stored attributes of each associated individual cable environment parameter.

Here, the pre-stored attributes may be the pre-stored attribute contents (e.g., weight, factor influence level and other attributes) of the cable environment parameters. The final analysis value may be the value of a combined effect on a cable operational quality influencing factor from the ambient environment of a cable. In an embodiment, in the presence of a plurality of cable environment parameter influencing values for each of the cable operational quality influencing factors, a final analysis value for the cable operational quality influencing factor is determined by calculations based on the individual cable environment parameter influencing values of the cable operational quality influencing factor and a preset weight of each associated cable environment parameter. Optionally, the pre-stored attributes include influencing levels of the cable environment parameters on the associated individual cable operational quality influencing factors. For the presence of a plurality of cable environment parameter influencing values for each of the cable operational quality influencing factors, a method for determining a final analysis value may include: determining corresponding influencing weights respectively based on the influencing levels of the associated individual cable environment parameters on the cable operational quality influencing factor, and performing multiplication and superposition on the individual cable environment parameter influencing values of the cable operational quality influencing factor and the corresponding influencing weights, respectively, to obtain the final analysis value of the cable operational quality influencing factor. The corresponding influencing weights are determined based on the influencing levels of the associated individual cable environment parameters on the cable operational quality influencing factors, and the final analysis values are then calculated based on the individual influencing weights and the individual cable environment parameter influencing values of the cable operational quality influencing factors. In this way, the accuracy and rationality of the final analysis values of the cable operational quality influencing factors can be improved.

In step S103, in the presence of one cable environment parameter influencing value for each of the cable operational quality influencing factors, the cable environment parameter influencing value is determined as a final analysis value for the cable operational quality influencing factor.

Here, evaluation rules are preset. For the cable operational quality evaluation value, in an embodiment, after the final analysis values of the individual cable operational quality influencing factors are determined, a corresponding pre-stored operational quality evaluation value mapping table is retrieved respectively based on the individual final analysis values to obtain corresponding evaluation values to be calculated, and the individual evaluation values to be calculated and the preset weights of the corresponding cable operational quality influencing factors are multiplied and superposed to obtain the cable operational quality evaluation value. Optionally, a method for determining the cable operational quality evaluation value may include: retrieving a corresponding pre-stored operational quality evaluation value mapping table respectively based on the individual final analysis values to obtain corresponding evaluation values to be calculated, comparing the evaluation values to be calculated with a preset standard value, determining whether an evaluation value to be calculated that is lower than the preset standard value is present, and determining the cable operational quality evaluation value based on a determination result and the individual evaluation values to be calculated. The cable operational quality evaluation value is determined based on the comparison result between the evaluation values to be calculated corresponding to the final analysis values and the preset standard value, as well as the individual evaluation values to be calculated. In this way, the accuracy and rationality of the cable operational quality can be improved.

As can be seen from above, the collected data of the individual cable environment parameters within the preset time period and the plurality of associated cable operational quality influencing factorsof individual cablesare acquired; the cable environment parameter influencing values of the individual cable operational quality influencing factors are determined correspondingly based on the collected data of the individual cable environmental parameters; in the presence of a plurality of cable environment parameter influencing values for each of the cable operational quality influencing factors, a final analysis value is determined based on the individual cable environment parameter influencing values of the cable operational quality influencing factor and the pre-stored attributes of each associated cable environment parameter; and in the presence of one cable environment parameter influencing value for each of the operational quality influencing factors, the cable environment parameter influencing value is determined as a final analysis value for the operational quality influencing factor.

In step S104, the cable operational quality evaluation value is determined based on the individual final analysis values and the preset evaluation rules.

In this solution, the problem that the lack of references regarding cable operational quality influencing factors in the related art results in poor rationality of cable operational quality is solved, and the cable operational quality can be determined by monitoring the environment parameters during cable operation, thereby improving the accuracy and rationality of the cable operational quality.

FIG. 2 shows a flowchart of another method for determining cable operational quality based on an environment where a cable is located according to an embodiment of the present application, providing a specific optional method for determining cable environment parameter influencing values of the cable operational quality influencing factors. As shown in FIG. 2, the method specifically includes the steps as follows.

In step S201, collected data of individual cable environment parameters within a preset time period and a plurality of associated cable operational quality influencing factors of individual cables are acquired, the individual cable environment parameters and the plurality of corresponding associated cable operational quality influencing factors are combined into a plurality of combinations to be matched, respectively, and matching is performed based on the plurality of combinations to be matched and a plurality of pre-stored matching combinations.

Here, the pre-stored matching combinations are used to represent the pre-stored combinations of cable environment parameters and cable operational quality influencing factors for the purpose of matching. In an illustrative example, it is possible that the individual cable environment parameters are temperature, humidity and oxygen concentration, respectively. The temperature is associated with a plurality of cable operational quality influencing factors such as fire probability and short-circuit probability; the humidity is associated with a plurality of cable operational quality influencing factors such as short-circuit probability and electric leakage probability; and the oxygen concentration is associated with a plurality of cable operational quality influencing factors such as fire probability and short-circuit probability. The individual cable environment parameters and the plurality of corresponding associated cable operational quality influencing factors are respectively combined into a plurality of combinations to be matched, namely (temperature, fire probability), (temperature, short-circuit probability), (humidity, short-circuit probability), (humidity, electric leakage probability), (oxygen concentration, fire probability), and (oxygen concentration, short-circuit probability). The pre-stored matching combinations are: Combination A (oxygen concentration, short-circuit probability), Combination B (oxygen concentration, fire probability), Combination C (humidity, electric leakage probability), Combination D (humidity, short-circuit probability), Combination E (temperature, short-circuit probability), and Combination F (temperature, fire probability), respectively. The combination (temperature, fire probability) to be matched successfully matches Combination F; the combination (temperature, short-circuit probability) to be matched successfully matches Combination E; the combination (humidity, short-circuit probability) to be matched successfully matches Combination D; the combination (humidity, electric leakage probability) to be matched successfully matches Combination C; the combination (oxygen concentration, fire probability) to be matched successfully matches Combination B; and the combination (oxygen concentration, short-circuit probability) to be matched successfully matches Combination A.

In step S202, calculation is performed on the collected data of the individual cable environment parameters based on a matching result to obtain the cable environment parameter influencing values of the individual cable operational quality influencing factors.

Here, in an embodiment, the average value of the collected data of each cable environment parameter is calculated; the standard and percentage values associated with the pre-stored matching combination that successfully matches the combination to be matched are acquired; and the average value of the cable environment parameter in the combination to be matched and the corresponding standard and percentage values are substituted into a preset calculation formula, namely, (average value/standard value)*percentage value. Optionally, a method for calculation may include: acquiring pre-stored influencing value calculation formulas associated with the pre-stored matching combinations that successfully match the individual combinations to be matched, and performing calculation by substituting the collected data of the cable environment parameters in the individual combinations to be matched into the corresponding pre-stored influencing value calculation formulas, respectively. In an illustrative example, it is possible that the combination (temperature, short-circuit probability) to be matched successfully matches Combination D, and the calculation formula for the pre-stored influencing value associated with Combination D is: (average temperature/preset temperature)*preset percentage, in which the preset temperature is 40° C., the preset percentage is 48%, and the collected data of the temperature within 30 min (the preset time period) include 48° C., 50° C. and 52° C., with the average temperature of 50° C., which is then substituted into the calculation formula to obtain the temperature influencing value of 60% for the short-circuit probability.

In step S203, in the presence of a plurality of cable environment parameter influencing values for each of the cable operational quality influencing factors, a final analysis value for the cable operational quality influencing factor is determined based on the individual cable environment parameter influencing values of the cable operational quality influencing factor and pre-stored attributes of each associated individual cable environment parameter.

In step S204, in the presence of one cable environment parameter influencing value for each of the cable operational quality influencing factors, the cable environment parameter influencing value is determined as a final analysis value for the cable operational quality influencing factor, and a cable operational quality evaluation value is determined based on the individual final analysis values and preset evaluation rules.

As can be seen from above, the individual cable environment parameters and the plurality of corresponding associated cable operational quality influencing factors are combined into a plurality of combinations to be matched, respectively; matching is performed based on the plurality of combinations to be matched and a plurality of pre-stored matching combinations; and calculation is performed on the collected data of the individual cable environment parameters based on a matching result, respectively, to obtain the cable environment parameter influencing values of the individual cable operational quality influencing factors. In this solution, the cable environment parameters and the plurality of corresponding associated cable operational quality influencing factors are combined, matching is then performed based on the individual combinations, and the calculation is performed on the collected data of the cable environment parameters based on the matching result. In this way, the cable environment parameter influencing values of the individual cable operational quality influencing factors can be calculated rapidly and accurately.

FIG. 3 shows a flowchart of another method for determining cable operational quality based on an environment where a cable is located according to an embodiment of the present application, providing a specific optional method for determining final analysis values of the cable operational quality influencing factors. As shown in FIG. 3, the method specifically includes the steps as follows.

In step S301, collected data of individual cable environment parameters within a preset time period and a plurality of associated cable operational quality influencing factors of individual cablesare acquired, and cable environment parameter influencing values of the individual cable operational quality influencing factors are determined correspondingly based on the collected data of the individual cable environmental parameters.

In step S302, in the presence of a plurality of cable environment parameter influencing values for each of the cable operational quality influencing factors, corresponding influencing weights are determined respectively based on the influencing levels of the associated individual cable environment parameters on the cable operational quality influencing factor, and multiplication and superposition are performed on the individual cable environment parameter influencing values and the corresponding influencing weights, respectively, to obtain the final analysis value of the cable operational quality influencing factor.

Here, the pre-stored attributes include the influencing values of the cable environment parameters on the associated individual cable operational quality influencing factors. The influencing weights may refer to the degree of importance to which the cable environment parameters affect the cable operational quality influencing factors. Optionally, a method for determining an influencing weight may include: accumulating the influencing levels of the associated individual cable environment parameters on the cable operational quality influencing factors to obtain a sum of levels; calculating influencing level proportions corresponding to the associated individual cable environment parameters based on the sum of levels and the individual influencing levels, respectively; and determining the influencing level proportions as the influencing weights of the corresponding cable environment parameters on the cable operational quality influencing factor. In an illustrative example, it is possible that a plurality of cable environment parameter influencing values exist for the short-circuit probability, namely, the temperature influencing values of 60%, 20% and 40%; the influencing level of temperature on the short-circuit probability is level 4; the influencing level of humidity on the short-circuit probability is level 3; the influencing level of oxygen concentration on the short-circuit probability is level 3; and the sum of levels is 10 levels, with the influencing level proportion of temperature being 0.4 (4/10 ), the influencing level proportion of humidity being 0.3 (3/10 ), and the influencing level proportion of oxygen concentration being 0.3 (3/10 ). That is, the influencing weight of temperature on the short-circuit probability is 0.4, the influencing weight of humidity on the short-circuit probability is 0.3, the influencing weight of oxygen concentration on the short-circuit probability is 0.3, and the final analysis value of the short-circuit probability is 42% (60%*0.4+20%*0.3+40%*0.3). In another embodiment, the preset weights respectively corresponding to the influencing levels of the associated individual cable environment parameters on the cable operational quality influencing factor are determined as the influencing weights of the associated individual cable environment parameters on the cable operational quality influencing factor.

In step S303, in the presence of one cable environment parameter influencing value for each of the cable operational quality influencing factors, the cable environment parameter influencing value is determined as a final analysis value for the cable operational quality influencing factor; and a cable operational quality evaluation value is determined based on the individual final analysis values and preset evaluation rules.

As can be seen from above, in this solution, the corresponding influencing weights are determined respectively based on the influencing levels of the associated individual cable environment parameters on the cable operational quality influencing factor, and the individual cable environment parameter influencing values of the cable operational quality influencing factor and the corresponding influencing weights are multiplied and superposed, respectively, to obtain the final analysis value of the cable operational quality influencing factor. The corresponding influencing weights are determined based on the influencing levels of the associated individual cable environment parameters on the cable operational quality influencing factors, and the final analysis values are then calculated based on the individual influencing weights and the individual cable environment parameter influencing values of the cable operational quality influencing factors. In this way, the accuracy and rationality of the final analysis values of the cable operational quality influencing factors can be improved.

FIG. 4 shows a flowchart of another method for determining cable operational quality based on an environment where a cable is located according to an embodiment of the present application, providing a specific optional method for determining a cable operational quality evaluation value. As shown in FIG. 4, the method specifically includes the steps as follows.

In step S401, collected data of individual cable environment parameters within a preset time period and a plurality of associated cable operational quality influencing factors of individual cablesare acquired, and cable environment parameter influencing values of the individual cable operational quality influencing factors are determined correspondingly based on the collected data of the individual cable environmental parameters.

In step S402, in the presence of a plurality of cable environment parameter influencing values for each of the cable operational quality influencing factors, a final analysis value for the cable operational quality influencing factor is determined based on the individual cable environment parameter influencing values of the cable operational quality influencing factor and pre-stored attributes of each associated individual cable environment parameter.

In step S403, in the presence of one cable environment parameter influencing value for each of the cable operational quality influencing factors, the cable environment parameter influencing value is determined as a final analysis value for the cable operational quality influencing factor.

In step S404, a corresponding pre-stored operational quality evaluation value mapping table is queried respectively based on the individual final analysis values to obtain corresponding evaluation values to be calculated, the evaluation values to be calculated are compared with a preset standard value, whether an evaluation value to be calculated that is lower than the preset standard value is present is determined, and the cable operational quality evaluation value is determined based on a determination result and the individual evaluation values to be calculated.

Here, the pre-stored operational quality evaluation value mapping table may be a pre-stored comparison table between the final analysis values of the cable operational quality influencing factors and the evaluation values to be calculated. The evaluation value to be calculated may be a unilateral evaluation value of the cable operational quality based on a cable operational quality influencing factor. With this evaluation vale to be calculated, the cable operational quality evaluation value may be calculated. Optionally, a method for calculating the cable operational quality evaluation value may include: performing multiplication and superposition on the individual evaluation values to be calculated and the preset weights of the corresponding cable operational quality influencing factors to obtain the operational quality evaluation value to be determined; in the absence of an evaluation value to be calculated that is lower than the preset standard value, determining the operational quality evaluation value to be determined, as the cable operational quality evaluation value; and in the presence of an evaluation value to be calculated that is lower than the preset standard value, determining a number of evaluation values to be calculated that are lower than the preset standard value, retrieving a preset quality down-regulation value corresponding to the number, and subtracting the quality down-regulation value from the operational quality evaluation value to be determined to obtain the cable operational quality evaluation value. In an illustrative example, it is possible that by retrieving, the final analysis value of the fire probability corresponds to the evaluation value to be calculated of 55 points, the final analysis value of the short-circuit probability corresponds to the evaluation value to be calculated of 45 points, and the final analysis value of the electric leakage probability corresponds to the evaluation value to be calculated of 90 points; the preset weight of the fire probability is 0.5, the preset weight of the short-circuit probability is 0.3, and the preset weight of the electric leakage probability is 0.2; the preset standard value is 60 points; the evaluation values to be calculated and the preset weights of the corresponding cable operational quality influencing factors are multiplied and superposed to obtain the operation quality evaluation value to be determined of 59 points; the number of the evaluation values to be calculated lower than the preset standard value is 2, which corresponds to a preset quality down-regulation value of 10 points; and then, 10 points is subtracted from 59 points to give the cable operational quality evaluation value of 49 points.

In another embodiment, the individual evaluation values to be calculated and the preset weights of the corresponding cable operational quality influencing factors are multiplied and superposed to obtain the cable operational quality evaluation value; in the absence of an evaluation value to be calculated that is lower than the preset standard value, the operational quality evaluation value to be determined is determined as the cable operational quality evaluation value; and in the presence of an evaluation value to be calculated that is lower than the preset standard value, a difference value between the evaluation value to be calculated that is lower than the preset standard value and the present standard value is calculated, a preset quality down-regulation value corresponding to the difference value is retrieved, and the quality down-regulation value is subtracted from the operational quality evaluation value to be determined to obtain the cable operational quality evaluation value.

As can be seen from above, a corresponding pre-stored operational quality evaluation value mapping table is queried respectively based on the individual final analysis values to obtain corresponding evaluation values to be calculated; the evaluation values to be calculated are compared with a preset standard value; whether an evaluation value to be calculated that is lower than the preset standard value is present is determined; and the cable operational quality evaluation value is determined based on a determination result and the individual evaluation values to be calculated. The cable operational quality evaluation value is determined based on the comparison result between the evaluation values to be calculated corresponding to the final analysis values and the preset standard value, as well as the individual evaluation values to be calculated. In this way, the accuracy and rationality of the cable operational quality can be improved.

FIG. 5 shows a block diagram of a modular structure of a system for determining cable operational quality based on an environment where a cable is located according to an embodiment of the present application. This system is configured for executing the method for determining cable operational quality based on the environment where the cable is located according to the embodiments described above, and has the corresponding modules for executing the method, as well as advantageous effects. As shown in FIG. 5, the system specifically includes:
an acquisition module 101 for acquiring collected data of individual cable environment parameters within a preset time period and a plurality of associated cable operational quality influencing factors of individual cables;
an influencing value determination module 102 for determining cable environment parameter influencing values of the individual cable operational quality influencing factors correspondingly based on the collected data of the individual cable environmental parameters;
an analysis value determination module 103 for determining, in the presence of a plurality of cable environment parameter influencing values for each of the cable operational quality influencing factors, a final analysis value for the cable operational quality influencing factor based on the individual cable environment parameter influencing values of the cable operational quality influencing factor and pre-stored attributes of each associated individual cable environment parameter;
the analysis value determination module 103 also for determining, in the presence of one cable environment parameter influencing value for each of the cable operational quality influencing factors, the cable environment parameter influencing value as a final analysis value for the cable operational quality influencing factor; and
an operational quality determination module 104 for determining a cable operational quality evaluation value based on the individual final analysis values and preset evaluation rules.

As can be seen from above solution, the collected data of the individual cable environment parameters within the preset time period and the plurality of associated cable operational quality influencing factors of individual cablesare acquired; the cable environment parameter influencing values of the individual cable operational quality influencing factors are determined correspondingly based on the collected data of the individual cable environmental parameters; in the presence of a plurality of cable environment parameter influencing values for each of the cable operational quality influencing factors, a final analysis value is determined based on the individual cable environment parameter influencing values of the cable operational quality influencing factor and the pre-stored attributes of each associated cable environment parameter; in the presence of one cable environment parameter influencing value for each of the operational quality influencing factors, the cable environment parameter influencing value is determined as a final analysis value for the cable operational quality influencing factor; and the cable operational quality evaluation value is determined based on the individual final analysis values and the preset evaluation rules. In this solution, the problem that the lack of references regarding cable operational quality influencing factors in the related art results in poor rationality of cable operational quality is solved, and the cable operational quality can be determined by monitoring the environment parameters during cable operation, thereby improving the accuracy and rationality of the cable operational quality.

In a possible embodiment, the influencing value determination module 102 is specifically configured for:
combining the individual cable environment parameters and the plurality of corresponding associated cable operational quality influencing factors into a plurality of combinations to be matched, respectively, and performing matching based on the plurality of combinations to be matched and a plurality of pre-stored matching combinations; and
performing calculation on the collected data of the individual cable environment parameters based on a matching result to obtain the cable environment parameter influencing values of the individual cable operational quality influencing factors.

In a possible embodiment, the influencing value determination module 102 is further configured for:
acquiring pre-stored influencing value calculation formulas associated with the pre-stored matching combinations that successfully match the individual combinations to be matched, and performing calculation by substituting the collected data of the cable environment parameters in the individual combinations to be matched into the corresponding pre-stored influencing value calculation formulas, respectively.

In a possible embodiment, the analysis value determination module 103 is specifically configured for:
determining corresponding influencing weights respectively based on the influencing levels of the associated individual cable environment parameters on the cable operational quality influencing factors, and performing multiplication and superposition on the individual cable environment parameter influencing values and the corresponding influencing weights, respectively, to obtain the final analysis values of the cable operational quality influencing factors.

In a possible embodiment, the analysis value determination module 103 is further configured for:
accumulating the influencing levels of the associated individual cable environment parameters on the cable operational quality influencing factors to obtain a sum of levels, and calculating influencing level proportions corresponding to the associated individual cable environment parameters based on the sum of levels and the individual influencing levels, respectively; and
determining the influencing level proportions as the influencing weights of the corresponding cable environment parameters on the cable operational quality influencing factor.

In a possible embodiment, the operational quality determination module 104 is specifically configured for:
retrieving a corresponding pre-stored operational quality evaluation value mapping table respectively based on the individual final analysis values to obtain corresponding evaluation values to be calculated, and comparing the evaluation values to be calculated with a preset standard value; and
determining whether an evaluation value to be calculated that is lower than the preset standard value is present, and determining the cable operational quality evaluation value based on a determination result and the individual evaluation values to be calculated.

In a possible embodiment, the operational quality determination module 104 is further configured for:
performing multiplication and superposition on each of the evaluation values to be calculated and a preset weight of a corresponding cable operational quality influencing factor to obtain an operational quality evaluation value to be determined;
in the absence of an evaluation value to be calculated that is lower than the preset standard value, determining the operational quality evaluation value to be determined, as the cable operational quality evaluation value;
in the presence of an evaluation value to be calculated that is lower than the preset standard value, determining a number of evaluation values to be calculated that are lower than the preset standard value, retrieving a preset quality down-regulation value corresponding to the number, and subtracting the quality down-regulation value from the operational quality evaluation value to be determined to obtain the cable operational quality evaluation value.

FIG. 6 shows a schematic structural diagram of a device for determining cable operational quality based on an environment where a cable is located according to an embodiment of the present application. As shown in FIG. 6, the device includes a processor 201, a memory 202, an input means 203 and an output means 204. The number of the processor(s) 201 in this device may be one or more, with one processor 201 taken as an example in FIG. 6. The processor 201, the memory 202, the input means 203 and the output means 204 in this device may be connected via a bus or in other ways, with a bus connection taken as an example in FIG. 6. As a computer-readable storage medium, the memory 202 may be configured for storing software programs, computer-executable programs and modules, for example, program instructions and modules corresponding to the method for determining cable operational quality based on the environment where the cable is located in the embodiments of the present application. The processor 201 executes various functional applications and data processing by running software programs, instructions and modules stored in the memory 202, thereby implementing the method for determining cable operational quality based on the environment where the cable is located as described above. The input means 203 may be configured for receiving input numeric or character information and generating key signal inputs related to user settings and functional control of the device. The output means 204 may include a display device such as a display screen.

An embodiment of the present application further provides a storage medium for storing a computer-executable instruction, and the computer-executable instruction, when executed by a computer processor, is configured to execute a method for determining cable operational quality based on an environment where a cable is located. The method includes:
acquiring collected data of individual cable environment parameters within a preset time period and a plurality of associated cable operational quality influencing factorsof individual cables, and determining cable environment parameter influencing values of the individual cable operational quality influencing factors correspondingly based on the collected data of the individual cable environmental parameters;
in the presence of a plurality of cable environment parameter influencing values for each of the cable operational quality influencing factors, determining a final analysis value for the cable operational quality influencing factor based on the individual cable environment parameter influencing values of the cable operational quality influencing factor and pre-stored attributes of each associated individual cable environment parameter;
in the presence of one cable environment parameter influencing value for each of the cable operational quality influencing factors, determining the cable environment parameter influencing value as a final analysis value for the cable operational quality influencing factor; and determining a cable operational quality evaluation value based on the individual final analysis values and preset evaluation rules.

It is worth noting that, in the embodiments of the method and system for determining cable operational quality based on the environment where the cable is located as described above, the various units and modules included are only divided according to a functional logic, and are not limited to the divisions described above, as long as the corresponding functionals can be achieved. In addition, the specific names of individual functional units are only for the convenience of distinguishing each other, and are not intended to limit the protection scope of the embodiments of the present application.

It should be noted that the above description only provides the preferred embodiments of the embodiments of the present application as well as the technical principle used therein. It will be appreciated by those skilled in the art that the embodiments of the present application are not limited to the specific embodiments described herein. Those skilled in the art can make various obvious variations, readjustments and substitutions without departing from the protection scope of the embodiments of the present application. Therefore, although the embodiments of the present application are illustrated in detail by means of the above embodiments, the embodiments of the present application are not limited only to the above embodiments, and many other equivalent embodiments can be further included without departing from the conception of the embodiments of the present application. The scope of the embodiments of the present application is subject to the scope defined by the appended claims.

What is claimed is:

1. A method for determining cable operational quality based on an environment where a cable is located, which is applied to a server, wherein the method comprises:
acquiring collected data of individual cable environment parameters within a preset time period and a plurality of associated cable operational quality influencing factors of individual cables, and determining cable environment parameter influencing values ofindividual cable operational quality influencing factors correspondingly based on the collected data of the individual cable environmental parameters;
in the presence of a plurality of cable environment parameter influencing values for each of the cable operational quality influencing factors, determining a final analysis value for the cable operational quality influencing factor based on the individual cable environment parameter influencing values of the cable operational quality influencing factor and pre-stored attributes of each associated individual cable environment parameter;
in the presence of one cable environment parameter influencing value for each of the cable operational quality influencing factors, determining the cable environment parameter influencing value as a final analysis value for the cable operational quality influencing factor; and
determining a cable operational quality evaluation value based on individual final analysis values and preset evaluation rules, comprising: retrieving a corresponding pre-stored operational quality evaluation value mapping table respectively based on the individual final analysis values to obtain corresponding evaluation values to be calculated, and comparing the evaluation values to be calculated with a preset standard value; and determining whether an evaluation value to be calculated that is lower than the preset standard value is present, and determining the cable operational quality evaluation value based on a determination result and individual evaluation values to be calculated.

2. The method for determining cable operational quality based on the environment where the cable is located according to claim 1, wherein determining the cable operational quality evaluation value based on the determination result and the individual evaluation values to be calculated comprises:
performing multiplication and superposition on each of the evaluation values to be calculated and a preset weight of a corresponding cable operational quality influencing factor to obtain an operational quality evaluation value to be determined;
in the absence of an evaluation value to be calculated that is lower than the preset standard value, determining the operational quality evaluation value to be determined, as the cable operational quality evaluation value;
in the presence of an evaluation value to be calculated that is lower than the preset standard value, determining a number of evaluation values to be calculated that are lower than the preset standard value, retrieving a preset quality down-regulation value corresponding to the number, and subtracting the quality down-regulation value from the operational quality evaluation value to be determined to obtain the cable operational quality evaluation value.

3. The method for determining cable operational quality based on the environment where the cable is located according to claim 1, wherein determining the cable environment parameter influencing values of the individual cable operational quality influencing factors correspondingly based on the collected data of the individual cable environmental parameters comprises:
combining the individual cable environment parameters and the plurality of corresponding associated cable operational quality influencing factors into a plurality of combinations to be matched, respectively, and performing matching based on the plurality of combinations to be matched and a plurality of pre-stored matching combinations; and
performing calculation on the collected data of the individual cable environment parameters based on a matching result to obtain the cable environment parameter influencing values of the individual cable operational quality influencing factors.

4. The method for determining cable operational quality based on the environment where the cable is located according to claim 3, wherein performing calculation on the collected data of the individual cable environment parameters based on the matching result comprises:
acquiring pre-stored influencing value calculation formulas associated with the pre-stored matching combinations that successfully match individual combinations to be matched, and performing calculation by substituting the collected data of the cable environment parameters in the individual combinations to be matched into the corresponding pre-stored influencing value calculation formulas, respectively.

5. The method for determining cable operational quality based on the environment where the cable is located according to claim 1, wherein the pre-stored attributes comprises influencing levels of the cable environment parameters on the associated individual cable operational quality influencing factors, and determining the final analysis values for the cable operational quality influencing factors based on the individual cable environment parameter influencing values of the cable operational quality influencing factors and the pre-stored attributes of the associated individual cable environment parameters comprises:
determining corresponding influencing weights respectively based on the influencing levels of the associated individual cable environment parameters on the cable operational quality influencing factors, and performing multiplication and superposition on the individual cable environment parameter influencing values and the corresponding influencing weights, respectively, to obtain the final analysis values of the cable operational quality influencing factors.

6. The method for determining cable operational quality based on the environment where the cable is located according to claim 5, wherein determining the corresponding influencing weights respectively based on the influencing levels of the associated individual cable environment parameters on the cable operational quality influencing factors comprises:
accumulating the influencing levels of the associated individual cable environment parameters on the cable operational quality influencing factors to obtain a sum of levels, and calculating influencing level proportions corresponding to the associated individual cable environment parameters based on the sum of levels and individual influencing levels, respectively; and
determining the influencing level proportions as the influencing weights of the corresponding cable environment parameters on the cable operational quality influencing factor.

7. An device for determining cable operational quality based on an environment where a cable is located, comprising: one or more processors; and a storage means for storing one or more programs, wherein the one or more programs, when executed by the one or more processors, cause the one or more processors to implement the method for determining cable operational quality based on the environment where the cable is located according to claim 1.

8. The device for determining cable operational quality based on the environment where the cable is located according to claim 7, wherein determining the cable operational quality evaluation value based on the determination result and the individual evaluation values to be calculated comprises:
performing multiplication and superposition on each of the evaluation values to be calculated and a preset weight of a corresponding cable operational quality influencing factor to obtain an operational quality evaluation value to be determined;
in the absence of an evaluation value to be calculated that is lower than the preset standard value, determining the operational quality evaluation value to be determined, as the cable operational quality evaluation value;
in the presence of an evaluation value to be calculated that is lower than the preset standard value, determining a number of evaluation values to be calculated that are lower than the preset standard value, retrieving a preset quality down-regulation value corresponding to the number, and subtracting the quality down-regulation value from the operational quality evaluation value to be determined to obtain the cable operational quality evaluation value.

9. The device for determining cable operational quality based on the environment where the cable is located according to claim 7, wherein determining the cable environment parameter influencing values of the individual cable operational quality influencing factors correspondingly based on the collected data of the individual cable environmental parameters comprises:
combining the individual cable environment parameters and the plurality of corresponding associated cable operational quality influencing factors into a plurality of combinations to be matched, respectively, and performing matching based on the plurality of combinations to be matched and a plurality of pre-stored matching combinations; and
performing calculation on the collected data of the individual cable environment parameters based on a matching result to obtain the cable environment parameter influencing values of the individual cable operational quality influencing factors.

10. The device for determining cable operational quality based on the environment where the cable is located according to claim 9, wherein performing calculation on the collected data of the individual cable environment parameters based on the matching result comprises:
acquiring pre-stored influencing value calculation formulas associated with the pre-stored matching combinations that successfully match individual combinations to be matched, and performing calculation by substituting the collected data of the cable environment parameters in the individual combinations to be matched into the corresponding pre-stored influencing value calculation formulas, respectively.

11. The device for determining cable operational quality based on the environment where the cable is located according to claim 7, wherein the pre-stored attributes comprises influencing levels of the cable environment parameters on the associated individual cable operational quality influencing factors, and determining the final analysis values for the cable operational quality influencing factors based on the individual cable environment parameter influencing values of the cable operational quality influencing factors and the pre-stored attributes of the associated individual cable environment parameters comprises:
determining corresponding influencing weights respectively based on the influencing levels of the associated individual cable environment parameters on the cable operational quality influencing factors, and performing multiplication and superposition on the individual cable environment parameter influencing values and the corresponding influencing weights, respectively, to obtain the final analysis values of the cable operational quality influencing factors.

12. The device for determining cable operational quality based on the environment where the cable is located according to claim 11, wherein determining the corresponding influencing weights respectively based on the influencing levels of the associated individual cable environment parameters on the cable operational quality influencing factors comprises:
accumulating the influencing levels of the associated individual cable environment parameters on the cable operational quality influencing factors to obtain a sum of levels, and calculating influencing level proportions corresponding to the associated individual cable environment parameters based on the sum of levels and individual influencing levels, respectively; and
determining the influencing level proportions as the influencing weights of the corresponding cable environment parameters on the cable operational quality influencing factor.

13. A storage medium for storing a computer-executable instruction, wherein the computer-executable instruction, when executed by a computer processor, is configured to execute the method for determining cable operational quality based on the environment where the cable is located according to claim 1.

14. The storage medium for storing the computer-executable instruction according to claim 13, wherein determining the cable operational quality evaluation value based on the determination result and the individual evaluation values to be calculated comprises:
performing multiplication and superposition on each of the evaluation values to be calculated and a preset weight of a corresponding cable operational quality influencing factor to obtain an operational quality evaluation value to be determined;
in the absence of an evaluation value to be calculated that is lower than the preset standard value, determining the operational quality evaluation value to be determined, as the cable operational quality evaluation value;
in the presence of an evaluation value to be calculated that is lower than the preset standard value, determining a number of evaluation values to be calculated that are lower than the preset standard value, retrieving a preset quality down-regulation value corresponding to the number, and subtracting the quality down-regulation value from the operational quality evaluation value to be determined to obtain the cable operational quality evaluation value.

15. The storage medium for storing the computer-executable instruction according to claim 13, wherein determining the cable environment parameter influencing values of the individual cable operational quality influencing factors correspondingly based on the collected data of the individual cable environmental parameters comprises:
combining the individual cable environment parameters and the plurality of corresponding associated cable operational quality influencing factors into a plurality of combinations to be matched, respectively, and performing matching based on the plurality of combinations to be matched and a plurality of pre-stored matching combinations; and
performing calculation on the collected data of the individual cable environment parameters based on a matching result to obtain the cable environment parameter influencing values of the individual cable operational quality influencing factors.

16. The storage medium for storing the computer-executable instruction according to claim 15, wherein performing calculation on the collected data of the individual cable environment parameters based on the matching result comprises:
acquiring pre-stored influencing value calculation formulas associated with the pre-stored matching combinations that successfully match individual combinations to be matched, and performing calculation by substituting the collected data of the cable environment parameters in the individual combinations to be matched into the corresponding pre-stored influencing value calculation formulas, respectively.

17. The storage medium for storing the computer-executable instruction according to claim 13, wherein the pre-stored attributes comprises influencing levels of the cable environment parameters on the associated individual cable operational quality influencing factors, and determining the final analysis values for the cable operational quality influencing factors based on the individual cable environment parameter influencing values of the cable operational quality influencing factors and the pre-stored attributes of the associated individual cable environment parameters comprises:
determining corresponding influencing weights respectively based on the influencing levels of the associated individual cable environment parameters on the cable operational quality influencing factors, and performing multiplication and superposition on the individual cable environment parameter influencing values and the corresponding influencing weights, respectively, to obtain the final analysis values of the cable operational quality influencing factors.

18. The storage medium for storing the computer-executable instruction according to claim 17, wherein determining the corresponding influencing weights respectively based on the influencing levels of the associated individual cable environment parameters on the cable operational quality influencing factors comprises:
accumulating the influencing levels of the associated individual cable environment parameters on the cable operational quality influencing factors to obtain a sum of levels, and calculating influencing level proportions corresponding to the associated individual cable environment parameters based on the sum of levels and individual influencing levels, respectively; and
determining the influencing level proportions as the influencing weights of the corresponding cable environment parameters on the cable operational quality influencing factor.
